(19) United States
(12) Patent Application Publication
(10) Pub. No.: US 2010/0294358 A1
(43) Pub. Date: Nov. 25, 2010

(54) SEMICONDUCTOR PACKAGE

(76) Inventors: Hiroyuki NAKANISHI, Osaka-shi (JP); Masahiro Okita, Osaka-shi (JP); Kohji Miyata, Osaka-shi (JP); Tomotoshi Satoh, Osaka-shi (JP); Etsuko Ishizuka, Osaka-shi (JP); Masato Yokobayashi, Osaka-shi (JP)

Correspondence Address: NIXON & VANDERHYE, PC, 901 NORTH GLEBE ROAD, 11TH FLOOR, ARLINGTON, VA, 22203, US

(21) Appl. No.: 12/783,283

(22) Filed: May 19, 2010

(30) Foreign Application Priority Data
May 22, 2009 (JP) 2009-124667
Jun. 29, 2009 (JP) 2009-154168

(51) Int. Cl. H01L 23/488; H01L 31/02

(52) U.S. Cl. 136/256; 257/741; 257/E23.023; 257/E31.11

(57) ABSTRACT

A semiconductor chip and an interposer are bonded by a conductive die bonding material. Between the semiconductor chip and the interposer, an application region in which the die bonding material resides and a region in which a sealing resin resides are provided. This allows adhesivity between the semiconductor chip and the interposer to be higher than that in conventional semiconductor packages, thereby causing no detachment at the adhesive interface. As a result, it becomes possible to improve electrical property and long-term reliability as compared to conventional semiconductor packages. Moreover, it is also possible to prevent the semiconductor chip from warping.

This Nonprovisional application claims priority under 35 U.S.C. §119(a) on Patent Application No. 2009-124667 filed in Japan on May 22, 2009, and on Patent Application No. 2009-154168 filed in Japan on Jun. 29, 2009, the entire contents of which are hereby incorporated by reference.

### TECHNICAL FIELD

The present invention relates to a semiconductor package.

### BACKGROUND ART

In a semiconductor package, semiconductor chips and an interposer are bonded by a die bonding material. More specifically, interposer connecting terminals, which are gold plated in most cases, are electrically connected with backsides of the semiconductor chips by conductive Ag paste (silver paste).

FIG. 13 is an illustrative drawing of a conventional semiconductor package 101. (a) of FIG. 13 is a cross-sectional view of the conventional semiconductor package 101, and (b) of FIG. 13 is a plane view of the conventional semiconductor package 101. In the semiconductor package 101, interposer connecting terminals 103 formed on a interposer 102 and plated with gold are electrically connected with backsides 104′ of semiconductor chips 104 via conductive Ag paste 105. The electrically connected semiconductor chips 104 are sealed with a sealing resin 106. In order to ensure the adhesivity between the sealing resin 106 and the interposer 102, a solder resist 107 is provided on the interposer 102.

As illustrated in the plane view of (b) of FIG. 13, the semiconductor package 101 includes interposer connecting terminals 103 each of which has such a size that the outline thereof almost corresponds to the outline of each semiconductor chip 104. For the sake of easy explanation, the sealing resin 106 and the solder resist 107 are omitted in (b) of FIG. 13. The Ag paste 105 is applied taking into consideration how the Ag paste 105 will be spread when the semiconductor chip 104 is mounted thereon, so that the Ag paste 105 after the mounting of the semiconductor chip 104 thereon will have such a size that its outline almost corresponds to the outline of the semiconductor chip 104.

Non Patent Literature 1 discloses a method for adhering semiconductor chips with use of resin in a conventional semiconductor package.

FIG. 26 is a cross-sectional view of a conventional semiconductor package 132. In the semiconductor package 132, a substrate wiring section 134 and a backside electrode 136 are bonded by a die bonding material (conductive adhesive) 137. The substrate wiring section 134 is provided on an interposer 133, and the backside electrode 136 is provided on a backside of a semiconductor chip 135. The semiconductor chip 135 and the interposer 133 are thus electrically connected via a die bonding material 137.

In FIG. 26, in a case where the semiconductor package 132 is a solar cell module, the semiconductor chip 135 is a solar cell. Here, the substrate wiring section 134 is made of, e.g., copper. The die bonding material 137 is, e.g., conductive silver paste. The backside electrode 136 is made of, e.g., burned aluminum.

### Citation List

Non Patent Literature 1

ISBN-88657-512-9, LSI Assembly Technique, p. 27 to 30, “2.3 Resin Adhesion Method”, Publisher: Triceps Corporation, Publication date: Mar. 31, 1987

### SUMMARY OF INVENTION

### Technical Problem

In the semiconductor package 101 of FIG. 13, the adhesivity at the interfaces between the Ag paste 105 and the backsides 104′ of the semiconductor chip 104 is low. Likewise, the adhesivity between the Ag paste 105 and the interposer connecting terminals 103 is also low. Consequently, in some cases, mechanical stress (external stress, internal stress) and/or physical stress (heat stress) applied on the semiconductor package 101 cause a partial or a complete detachment at an adhesive interface between the Ag paste 105 and the backsides 104′ of the semiconductor chips 104 or between the Ag paste 105 and the interposer connecting terminals 103.

Furthermore, the semiconductor package 101 of FIG. 13 has a layered structure made up of the interposer 102, the Ag paste 105, the semiconductor chips 104, and the sealing resin 106, which are made from different kinds of materials each having a different physical property. This causes the semiconductor package 101 to warp, which is a similar phenomenon to that found in a bimetal. Note that a bimetal is a lamination of two metal plates that have different coefficients of thermal expansion, respectively. The bimetal has such a property that it warps differently according to variations in temperature.

On this account, the problems that semiconductor packages are confronted are to prevent deterioration of electrical property and degradation of long-term reliability due to detachment at an adhesive interface, and to prevent a semiconductor chip from warping.

The present invention is achieved in view of the aforementioned problems, and an object of the present inventions is to provide a semiconductor package that has been improved in electrical property and long-term reliability as compared to conventional semiconductors and that make it possible to prevent a semiconductor chip from warping.

Meanwhile, conventional solar cell modules as illustrated in FIG. 26 are used for small-sized portable equipments. Therefore, solar cell modules are required to have such a structure that can endure such harsh environments as, not only high-temperature and high-humidity environments but also environments where external forces would be applied on the solar cell modules by being dropped, pressured, etc.

In addition, burned aluminum, which is used for the backside electrode 136 in FIG. 26, is relatively porous. Therefore, it is necessary to enhance the adhesivity at the interface between the backside electrode 136 made of burned aluminum and a die bonding material that is silver paste so as to endure the aforementioned harsh environments. On that basis, long-term reliability should be further improved.

The present invention is achieved in view of the aforementioned problem, and an object of the present invention is to provide a semiconductor package with improved long-term reliability as compared to conventional semiconductor packages.

### Solution to Problem

In order to attain the above objects, a semiconductor package according to the present invention includes: a semiconductor chip; an interposer on which the semiconductor chip is mounted; and a sealing resin covering the semiconductor chip on the interposer, and the semiconductor chip and the interposer are bonded by a conductive die bonding material, and the semiconductor package according to the present invention has, between the semiconductor chip and the interposer, a first region in which the die bonding material resides, and a second region in which the sealing resin resides.

According to the above invention, also the second region is filled with the sealing resin. Consequently, the first region having low adhesivity is reduced and surrounded by the second region having high adhesivity. This makes it possible for the semiconductor package to have higher adhesivity between the semiconductor chip and the interposer than conventional semiconductor packages so that no detachment occurs at the adhesive interface. As a result, it becomes possible to improve electrical property and long-term reliability as compared to conventional semiconductor packages.

In addition, the filling in the second region with the sealing resin causes the sealing resin to be sandwiched between the semiconductor chip and the interposer 2. As such, it becomes possible to prevent the semiconductor chip from warping.

In order to attain the above objects, a semiconductor package according to the present invention includes: a semiconductor chip; an interposer on which the semiconductor chip is mounted; and a sealing resin covering the semiconductor chip on the interposer, and in the semiconductor package according to the present invention, an electrode formed on a surface of the semiconductor chip, which surface faces the interposer, has a first region containing a first metal and a second region containing second metal, and the interposer and the electrode are electrically connected with each other by a conductive die bonding material containing the first metal.

According to the above invention, the conductive die bonding material contains the first metal. The adhesivity between the first metal and the conductive die bonding material containing the first metal is higher than the adhesivity between the second metal and the conductive die bonding material. As such, it becomes possible to make the adhesivity at the interface between the aforementioned electrode and the conductive die bonding material higher than the adhesivity at the interface between a conventional electrode and the conductive die bonding material. At the same time, contact resistance can be reduced. This makes it possible to provide a semiconductor package with improved long-term reliability as compared to conventional semiconductor packages.

Further, the second metal is relatively porous, and the conductive die bonding material containing the first metal contains an organic binder. In consequence, it is also expected that the stress applied on the semiconductor package be reduced.

### Advantageous Effects of Invention

As described above, in the semiconductor package according to the present invention, the semiconductor chip and the interposer are bonded by the conductive die bonding material, and the semiconductor package has, between the semiconductor chip and the interposer, the first region in which the die bonding material resides, and a second region in which the sealing resin resides.

Consequently, a semiconductor package is provided that makes it possible to improve electrical property and long-term reliability as compared to conventional semiconductor packages and to prevent the semiconductor chip from warping.

As described above, in the semiconductor package according to the present invention, the electrode formed on the surface of the semiconductor chip, which surface faces the interposer, has the first region containing the first metal and the second region containing the second metal, and the interposer and the electrode are electrically connected with each other by a conductive die bonding material containing the first metal.

This makes it possible to provide a semiconductor package with improved long-term reliability as compared to conventional semiconductor packages.

In addition, because the second metal is relatively porous, and the conductive die bonding material containing the first metal contains an organic binder, it is also expected that the stress applied on the semiconductor package be reduced.

### BRIEF DESCRIPTION OF DRAWINGS

FIG. 1 is an illustrative drawing of a semiconductor package according to an embodiment of the present invention: (a) is a cross-sectional view of the semiconductor package according to the embodiment of the present invention, and (b) is a plane view of the semiconductor package according to the embodiment of the present invention.

FIG. 2 is another plane view of a semiconductor package according to the embodiment of the present invention.

FIG. 3 is still another plane view of a semiconductor package according to the embodiment of the present invention.

FIG. 4 is still another plane view of a semiconductor package according to the embodiment of the present invention.

FIG. 5 is still another plane view of a semiconductor package according to the embodiment of the present invention.

FIG. 6 is still another plane view of a semiconductor package according to the embodiment of the present invention.

FIG. 7 is still another plane view of a semiconductor package according to the embodiment of the present invention.

FIG. 8 is an illustrative drawing of a solar cell module as an example of a semiconductor package according to the embodiment of the present invention: (a) is a plane view illustrating a front surface of the solar cell module as an example of the semiconductor package according to the embodiment of the present invention, (b) is a side view of the solar cell module, and (c) is a plane view illustrating a back surface of the solar cell module.

FIG. 9 is an illustrative drawing of a solar cell according to the embodiment of the present invention: (a) is a perspective view of the solar cell according to the embodiment of the present invention, (b) is a cross-sectional view of the solar cell taken along the line B-B, and (c) is an equivalent circuit diagram of a circuit including the solar cell module according to the embodiment of the present invention.

FIG. 10 is a drawing illustrating an example of use of a solar cell module according to the embodiment of the present invention: (a) is a side view of a cellular phone in an opened state, including the solar cell module according to the embodiment of the present invention, (b) is a top view of the cellular phone, (c) is a side view of the cellular phone in a closed state, and (d) is a bottom view of the cellular phone.

FIG. 11 is an illustrative drawing of a semiconductor package including connecting sections according to the embodiment of the present invention: (a) is a cross-sectional view of the semiconductor package including connecting sections according to the embodiment of the present invention taken along the line A-A, and (b) is a plane view of the semiconductor package including connecting sections according to the embodiment of the present invention.

FIG. 12 is a plane view illustrating an interposer, interposer connecting terminals, and solder resists before semiconductor chips are mounted.

FIG. 13 is an illustrative drawing of a conventional semiconductor package: (a) is a cross-sectional view of the conventional semiconductor package, and (b) is a plane view of the conventional semiconductor package.

FIG. 14 is a cross-sectional view of a semiconductor package according to an embodiment of the present invention.

FIG. 15 is an illustrative drawing of a semiconductor chip according to the embodiment of the present invention: (a) is a plane view of the semiconductor chip according to the embodiment of the present invention seen below its backside, (b) is a cross-sectional view of the semiconductor chip of (a) taken along the line A-A′, and (c) is a cross-sectional view of the semiconductor chip of (a) taken along the line B-B′.

FIG. 16 is a plane view of another semiconductor chip according to the embodiment of the present invention seen below its backside.

FIG. 17 is a plane view of still another semiconductor chip according to the embodiment of the present invention seen below its backside.

FIG. 18 is a plane view of still another semiconductor chip according to the embodiment of the present invention seen below its backside.

FIG. 19 is a plane view of still another semiconductor chip according to the embodiment of the present invention seen below its backside.

FIG. 20 is a plane view of still another semiconductor chip according to the embodiment of the present invention seen below its backside.

FIG. 21 is a plane view of still another semiconductor chip according to the embodiment of the present invention seen below its backside.

FIG. 22 is a plane view of still another semiconductor chip according to the embodiment of the present invention seen below its backside.

FIG. 23 is a plane view of still another semiconductor chip according to the embodiment of the present invention seen below its backside.

FIG. 24 is a plane view of still another semiconductor chip according to the embodiment of the present invention seen below its backside.

FIG. 25 is a plane view of still another semiconductor chip according to the embodiment of the present invention seen below its backside.

FIG. 26 is a cross-sectional view of a conventional semiconductor package.

### DESCRIPTION OF EMBODIMENTS

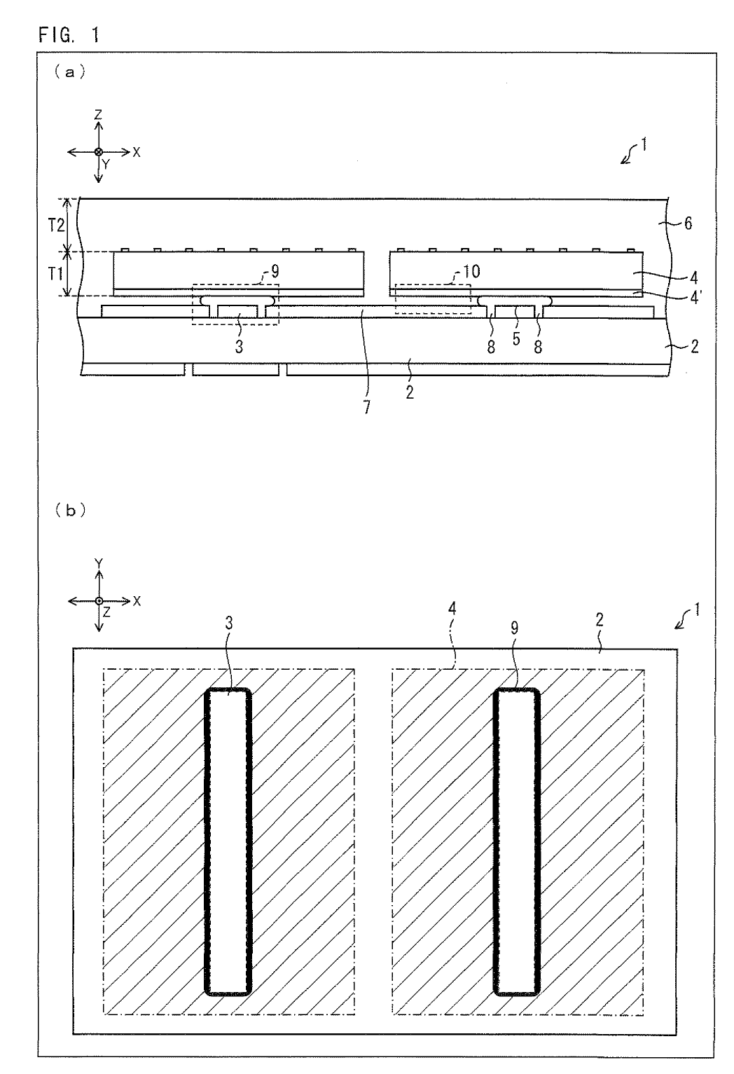

The following describes an embodiment of the present invention with reference to FIGS. 1 to 12.

FIG. 1 is an illustrative drawing of a semiconductor package 1 according to the embodiment of the present invention. (a) of FIG. 1 is a cross-sectional view of the semiconductor package 1 according to the embodiment of the present invention, and (b) of FIG. 1 is a plane view of the semiconductor package 1 according to the embodiment of the present invention. The semiconductor package 1 is configured such that interposer connecting terminals 3, which are formed on an interposer 2 and gold-plated, are electrically connected with backsides 4′ of semiconductor chips 4 via a conductive Ag paste 5 (silver paste, conductive die bonding material).

The electrically connected semiconductor chips 4 are sealed with a sealing resin 6. In order to ensure the adhesivity between the sealing resin 6 and the interposer 2, a solder resist 7 is provided on the interposer 2.

As illustrated in the plane view of (b) of FIG. 1, the semiconductor package 1 includes the interposer connecting terminals 3 that are smaller in size than the semiconductor chips 4, respectively. For the sake of easy explanation, the sealing resin 6 and the solder resist 7 are omitted in (b) of FIG. 1.

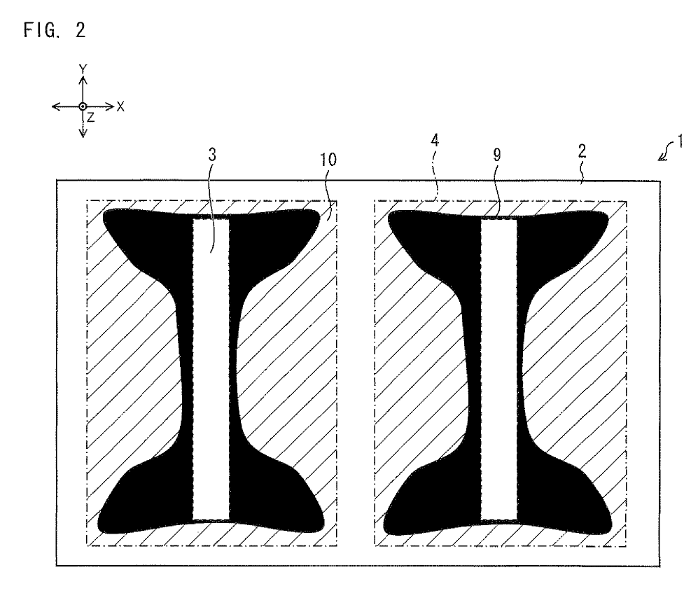

Each interposer connecting terminal 3 shown in (b) of FIG. 1 is a rectangle whose shorter sides are parallel to an X-direction and whose longer sides are parallel to a Y-direction. However, as illustrated in FIGS. 2 to 7 mentioned later, positions, shapes, and the number of the interposer connecting terminals 3 are not limited to those illustrated in (b) of FIG. 1.

In (b) of FIG. 1, application regions of the Ag paste 5, i.e., regions where the Ag paste 5 is applied, are, for example, approximately as large as the interposer connecting terminals 3. The contour of each application region 9 of the Ag paste 5, which will be described later, is defined based on a trench 8 illustrated in (a) of FIG. 1. The trench 8 is formed between the interposer connecting terminal 3 and the solder resist 7.

It is known that the adhesivity between the sealing resin 6 and targets to be adhered is higher than the adhesivity between the Ag paste 5 and targets to be adhered. To give a specific example with reference to FIG. 1, the adhesivity between the semiconductor chip 4 and the sealing resin 6 is greater than the adhesivity between the semiconductor chip 4 and the Ag paste 5. Likewise, the adhesivity between the sealing resin 6 and the interposer 2 is greater than the adhesivity between the Ag paste 5 and the interposer 2. Furthermore, the adhesivity between the sealing resin 6 and the solder resist 7 is greater than the adhesivity between the Ag paste 5 and the solder resist 7.

The above-described adhesive properties allow the semiconductor package 1 to have the interposer connecting terminals 3 of a smaller area, and a smaller application region (adhesion region) 9 of the Ag paste 5. In the application region 9 of the Ag paste 5, the Ag paste 5 and the backside 4′ of the semiconductor chip 4 are adhered. At the same time, the Ag paste 5 and the interposer connecting terminal 3 are adhered as well.

In the meantime, as described above, the interposer connecting terminals 3 are smaller in size than the semiconductor chips 4. Consequently, as illustrated in (a) of FIG. 1, between the semiconductor chip 4 and the solder resist 7 is provided a region 10 where the Ag paste 5 is not applied. In (b) of FIG. 10, the region 10 is represented by oblique lines. The semiconductor package 1 attains improved adhesivity by filling the region 10 with the sealing resin 6. The solder resist 7 not only forms the trench 8 but also ensures the adhesivity between the sealing resin 6 and the interposer 2.

In the semiconductor package 1, the region 10 is filled with the sealing resin 6. As such, the application region 9 with low adhesivity is reduced and surrounded by the region 10 with high adhesivity. This makes it possible that the adhesivity between the semiconductor chip 4 and the interposer 2, i.e., the adhesivity between the semiconductor chip 4 and the solder resist 7, be higher than that in conventional semiconductor packages. In consequence, no detachment occurs at the adhesive interface. As a result, it becomes possible to improve electrical property and long-term reliability.

In addition, by filling the sealing resin 6 in the region 10, the sealing resin 6 is sandwiched between the semiconductor chip 4 and the interposer 2. This makes it possible to prevent the semiconductor chip 4 from warping.

In a method of manufacturing the semiconductor package 1 including a semiconductor chip 4; an interposer 2 on which the semiconductor chip 4 is mounted; and a sealing resin 6 which is on the interposer 2 and covers the semiconductor chip 4, the method includes the steps of: providing a conductive die bonding material to the application region 9 in the region where the semiconductor chip 4 is to be mounted on the interposer 2; mounting the semiconductor chip 4 on the provided die bonding material; curing the die bonding material so that the interposer 2 and the semiconductor chip 4 are bonded; and providing the sealing resin 6 onto the interposer 2 by a transfer molding method, a potting method, or a printing method, and providing the sealing resin 6 to the region 10 where no die bonding material is provided in the region where the semiconductor chip 4 is to be mounted.

The following describes examples of the interposer connecting terminals 3 and the application regions 9 of the Ag paste 5 on the interposer 2 of the semiconductor package 1 with reference to FIGS. 2 to 7. In FIGS. 2 to 7, similarly to (b) of FIG. 1, the region 10 is represented by oblique lines, and the sealing resin 6 and the solder resist 7 are omitted.

FIG. 2 is another plane view of a semiconductor package according to the embodiment of the present invention. Similarly to the interposer connecting terminals 3 illustrated in (b) of FIG. 1, each interposer connecting terminal 3 in FIG. 2 is a rectangle whose shorter sides are parallel to an X-direction and whose longer sides are parallel to a Y-direction. A difference between FIG. 2 and (b) of FIG. 1 is the shape of each application area 9 of the Ag paste 5. In FIG. 2, the application area 9 of the Ag paste 5 is substantially in the shape of an “I”. In FIG. 2, the interposer connecting terminals 3 are within the respective application regions 9.

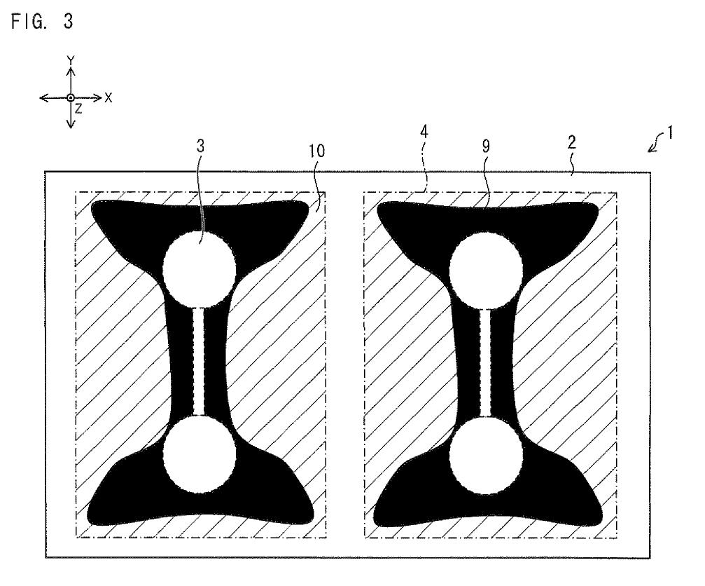

FIG. 3 is still another plane view of a semiconductor package 1 according to the embodiment of the present invention. Similarly to the application regions 9 of the Ag paste 5 in FIG. 2, each application region 9 of the Ag paste 5 in FIG. 3 is substantially in the shape of an “I”. A difference between FIG. 3 and FIG. 2 is the shape of each interposer connecting terminal 3. In FIG. 3, each interposer connecting terminal 3 has such a shape that a circular connecting terminal is connected to each shorter sides of a rectangular connecting terminal. Similarly to the interposer connecting terminals 3 in FIG. 2, the interposer connecting terminals 3 in FIG. 3 are within the respective application region 9.

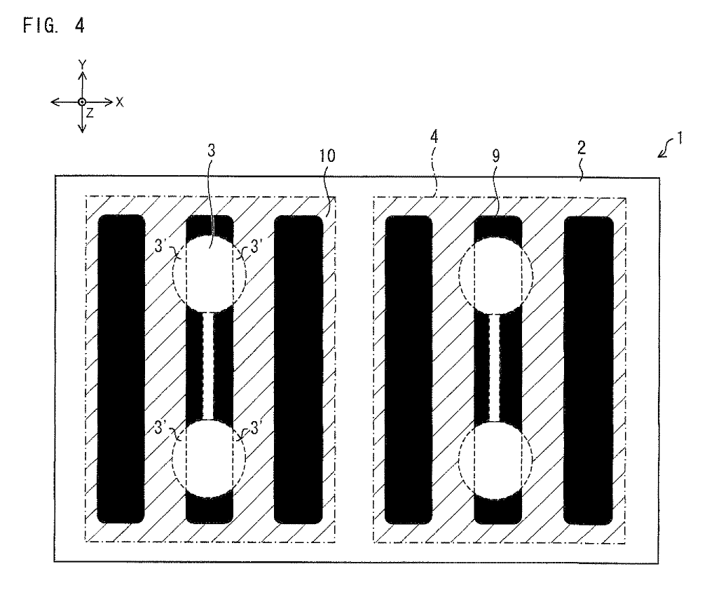

FIG. 4 is still another plane view of a semiconductor package 1 according to the embodiment of the present invention. Similarly to the interposer connecting terminals 3 in FIG. 3, each interposer connecting terminal 3 in FIG. 4 has such a shape that a circular connecting terminal is connected to each shorter sides of a rectangular connecting terminal. A difference between FIG. 4 and FIG. 3 is the shape of each application area 9 of the Ag paste 5. In FIG. 4, three rectangular application regions 9 whose longer sides are parallel to a Y-direction are aligned per semiconductor chip 4.

In the interposer connecting terminals 3 in FIG. 4, the parts denoted by a referential numeral 3′ protrude from the application regions 9 of the Ag paste 5. Here, similarly to the region 10, the regions between the semiconductor chips 4 and the parts 3′ are filled with the sealing resin 6. In this manner, the semiconductor package 1 may include both the application regions 9 of the Ag paste 5 and the regions that are filled with the sealing resin 6 between the semiconductor chips 4 and the interposer connecting terminals 3.

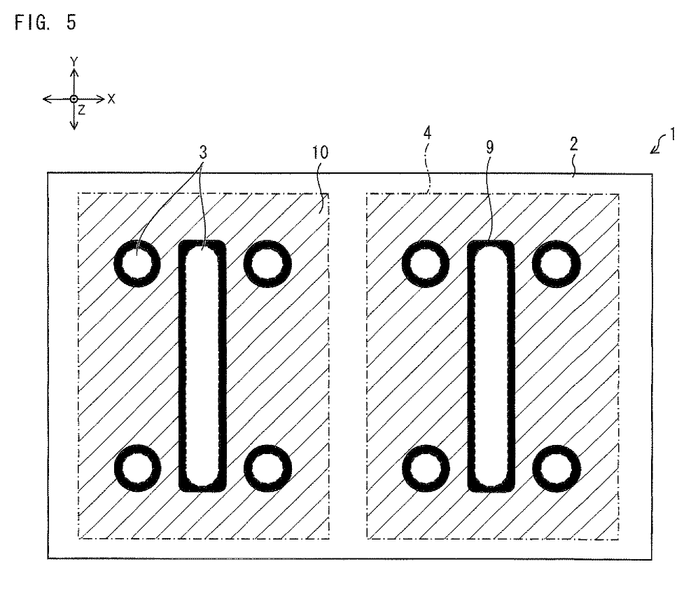

FIG. 5 is still another plane view of a semiconductor package 1 according to the embodiment of the present invention. The semiconductor package 1 of FIG. 5 includes a rectangular interposer connecting terminal 3 whose longer sides are parallel to a Y-direction and four circular interposer connecting terminals 3 per semiconductor chip 4. The rectangular interposer connecting terminal 3 is disposed in the central part of the semiconductor chip 4. The four circular interposer connecting terminals 3 are respectively disposed on the four corners of the semiconductor chip 4. As a result, each interposer connecting terminal 3 are arranged to form a shape of an “I”.

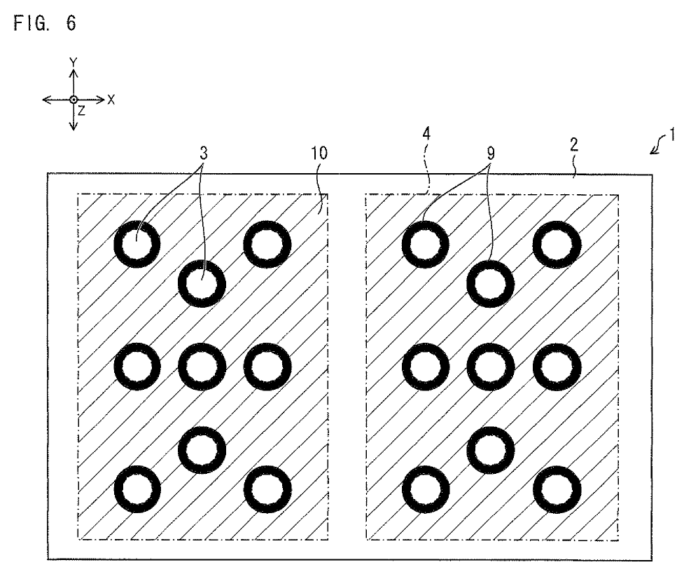

FIG. 6 is still another plane view of a semiconductor package 1 according to the embodiment of the present invention. The semiconductor package 1 in FIG. 6 includes nine circular interposer connecting terminals 3 per semiconductor chip 4. One of the circular interposer connecting terminal 3 is disposed in the central part of the semiconductor chip. On the left, right, top, and bottom thereof, four of the circular interposer terminals 3 are respectively disposed. In addition, on each of the four corners of each semiconductor chip 4, a circular interposer connecting terminal 3 is disposed. The nine circular interposer connecting terminals 3 respectively have circular application regions 9 of the Ag paste 5.

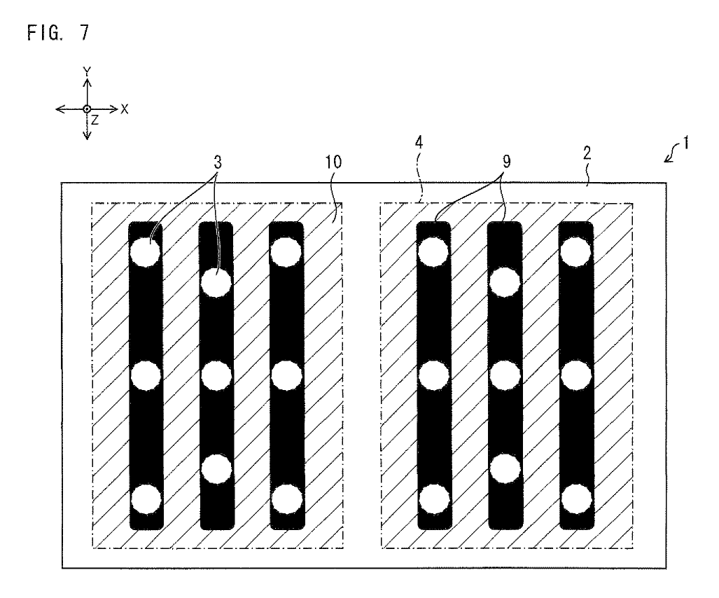

FIG. 7 is still another plane view of a semiconductor package 1 according to the embodiment of the present invention. Similarly to the semiconductor chips 4 in FIG. 6, each semiconductor chip 4 in FIG. 7 includes nine circular interposer connecting terminals. A difference between FIG. 7 and FIG. 6 is the shape of each application region 9 of the Ag paste 5. Three rectangular application regions 9 whose longer sides are parallel to a Y-direction are aligned per semiconductor chip 4. Three circular interposer connecting terminals 3 are connected to each rectangular application region 9.

As illustrated in above FIGS. 2 to 7, the positions, shapes, and number of the interposer connecting terminals 3 and the application regions 9 of the Ag paste 5 are optionally determined. This makes it possible to enhance the adhesivity between the semiconductor chip 4 and the interposer 2, i.e., the adhesivity between the semiconductor chip 4 and the solder resist 7 as compared to conventional semiconductor packages. Consequently, no detachment occurs at the adhesive interface. This makes it possible to improve electrical property and long-term reliability.

Furthermore, similarly to (b) of FIG. 1, by filling the region 10 with the sealing resin 6, the sealing resin 6 is sandwiched between the semiconductor chips 4 and the solder resists 7. This makes it possible to prevent the semiconductor chip 4 from warping.

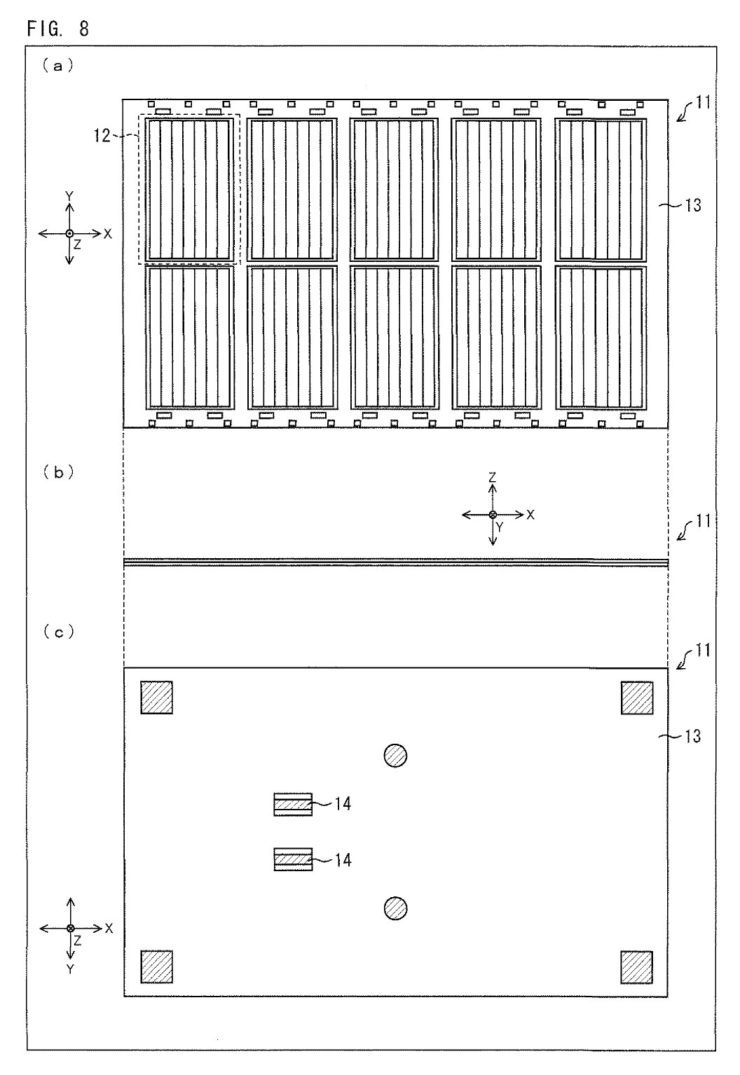

FIG. 8 is an illustrative drawing of a solar cell module 11 as an example of a semiconductor package 1 according to the embodiment of the present invention. (a) of FIG. 8 is a plane view illustrating a front surface of the solar cell module 11 as an example of the semiconductor package 1 according to the embodiment of the present invention. (b) of FIG. 8 is a side view of the solar cell module 11. (c) of FIG. 8 is a plane view illustrating a back surface of the solar cell module 11.

The solar cell module 11 includes ten solar cells 12. The solar cells 12 are arranged in a five-by-two matrix: each row of the matrix includes five solar cells 12 aligned along an X-direction, and each column of the matrix includes two solar cells 12 aligned along a Y-direction. Similarly to the semiconductor package in FIG. 1, interposer connecting terminals 3 and solder resists 7 are formed between the solar cells 12 and a module substrate 13. Moreover, similarly to the semiconductor package in FIG. 1, application regions (adhesive regions) 9 of the Ag paste 5 and the regions 10 to which the Ag paste 5 is not applied are provided between the solar cells 12 and the module substrate 13.

As illustrated in (c) of FIG. 8, on the backside of the solar cell module 11, mounting electrodes 14 are provided. When the solar cell module 11 is mounted on a mounting substrate (not illustrated), the mounting electrodes 14 are electrically connected with electrodes on the mounting substrate.

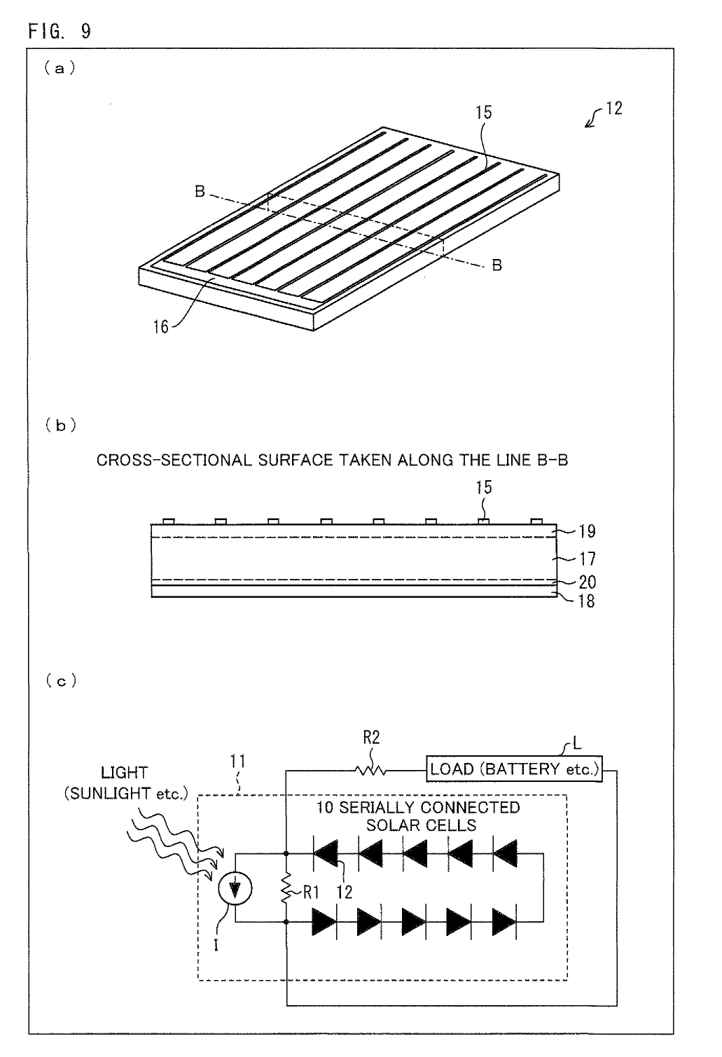

FIG. 9 is an illustrative drawing of a solar cell 12 according to the embodiment of the present invention. (a) of FIG. 9 is a perspective view of the solar cell 12 according to the embodiment of the present invention. (b) of FIG. 9 is a cross-sectional view of the solar cell 12 taken along the line B-B. (c) of FIG. 9 is an equivalent circuit diagram of a circuit including a solar module 11 according to the embodiment of the present invention.

As illustrated in the perspective view of (a) of FIG. 9 and the cross-sectional view of (b) of FIG. 9 taken along the line B-B, the solar cell 12 includes a sintered material 15, a connecting section 16, a p− layer 17 made of silicon, aluminum 18, an n+ layer 19, and a p+ layer 20. The sintered material 15 using aluminum and the connecting section 16 form a comb-like structure. It becomes possible to connect the solar cell 12 with other devices by performing wire bonding to the connecting section 16. A solar cell 12 is also included in the other devices.

In the equivalent circuit diagram of (c) of FIG. 9, the solar cell module 11 includes a current source I, a leakage current equivalent resistance R1, and ten serially connected solar cells 12 represented by symbols of diodes.

An input of the ten serially connected solar cells 12, an output of the current source I, and an end of the leakage current equivalent resistance R1 are connected to an end of a load L provided externally to the solar cell module 11. The load L is, for example, a battery.

The other end of the load L is connected to an end of a series resistance R2. The other end of the series resistance R2 is connected to an output of the ten serially connected solar cells 12, an input of the current supply I, and the other end of the leakage current equivalent resistance R1.

FIG. 10 illustrates an example of use of a solar cell module 11 according to the embodiment of the present invention. FIG. 10 shows a cellular phone 21 including the solar cell module 11. (a) of FIG. 10 is a side view of the cellular phone 21 in an opened state, (b) of FIG. 10 is a top view of the cellular phone 21, (c) of FIG. 10 is a side view of the cellular phone 21 in a closed state, and (d) of FIG. 10 is a bottom view of the cellular phone 21.

As illustrated in (a) of FIG. 10, the cellular phone 21 includes an operation surface 22 provided with buttons (not illustrated); a screen 23; a fulcrum 24; a camera 25; a battery cover 26; and two solar cell modules 11. The cellular phone 21 can be opened and closed by movement about the fulcrum 24.

On the backside of the operation surface 22, the solar cell module 11 and the battery cover 26 are provided. A battery (not illustrated) housed inside the battery cover 26 may be charged with use of the solar cell module 11. On the backside of the screen 23, the solar cell module 11 and the camera 25 are disposed.

In FIG. 10, the solar cell modules 11 are respectively provided on the top surface and the bottom surface of the cellular phone 12. However, their positions are not limited thereto. The solar cell module 11 may be provided to only one of the top and bottom surfaces.

FIG. 11 is an illustrative drawing of a semiconductor package 1 according to the embodiment of the present invention including a connecting section 16. (a) of FIG. 11 is a cross-sectional view of the semiconductor package 1 according to the embodiment of the present invention taken along the line A-A. (b) of FIG. 11 is a plane view of the semiconductor package 1 according to the embodiment of the present invention including a connecting section 16.

The semiconductor package 1 includes, on the front surface of each semiconductor chip 4, i.e., on the surface of each semiconductor chip 4 opposite to the surface facing the interposer 2, a connecting section 16 for electrically connecting the semiconductor chip 4 with the interposer 2. The interposer 2 and the connecting section 16 are bonded by wire bonding. The foregoing die bonding material may be provided on the surface of each semiconductor chip 4 facing the interposer 2 correspondingly to the connecting section 16 formed on the opposite surface of the semiconductor chip 4.

In a method of manufacturing a semiconductor package 1, on the front surface of each semiconductor chip 4, i.e., on the surface of each semiconductor chip 4 opposite to the surface facing the interposer 2, a connecting section 16 is provided for electrically connecting the semiconductor chip 4 with the interposer 2. The interposer 2 and the connecting section 16 are bonded by wire bonding. The foregoing die bonding material may be provided in the vicinity of the surface of each semiconductor chip 4 facing the interposer 2 correspondingly to the connecting section 16 formed on the opposite surface of the semiconductor chip 4, so that the die bonding material spreads toward the shorter sides of the semiconductor chip 4.

In some cases, the semiconductor chip and the interposer are electrically connected by wire bonding method. In such cases, the connecting section may be provided on a projecting portion (a part where no die bonding material is provided between the semiconductor chip and the interposer, i.e., a gap) of the semiconductor chip. When wire bonding is performed at this connecting section, the load caused thereby oscillates the semiconductor chip. This makes it difficult to carry out stable wire bonding. This phenomenon becomes prominent in accordance with that the semiconductor chip on the top is made thinner. A too thin semiconductor chip may break when wire bonding is performed.

In order to solve this problem, a die bonding material is provided on the surface of the semiconductor chip facing the interposer correspondingly to the connecting section formed on the opposite surface of the semiconductor chip. With this structure, it is possible to support the projecting portion of the semiconductor chip. This can restrain the oscillation of semiconductor chip arising from the load caused by wire bonding so that stable wire bonding can be performed between the connecting section of the semiconductor chip and the interposer.

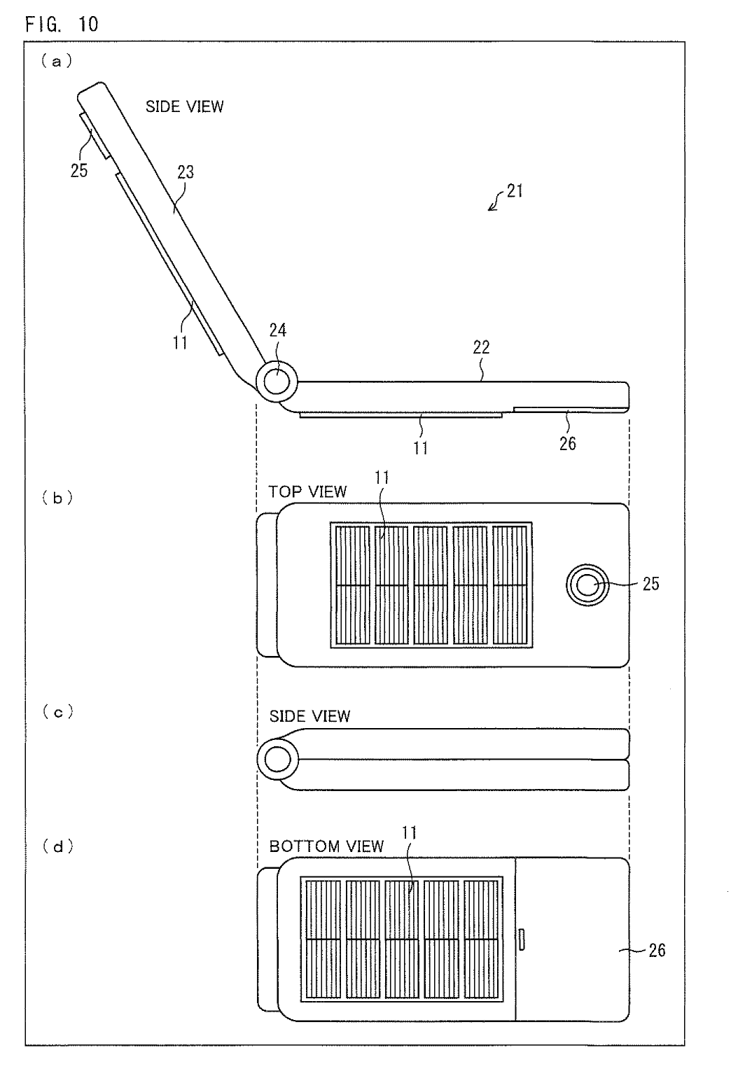

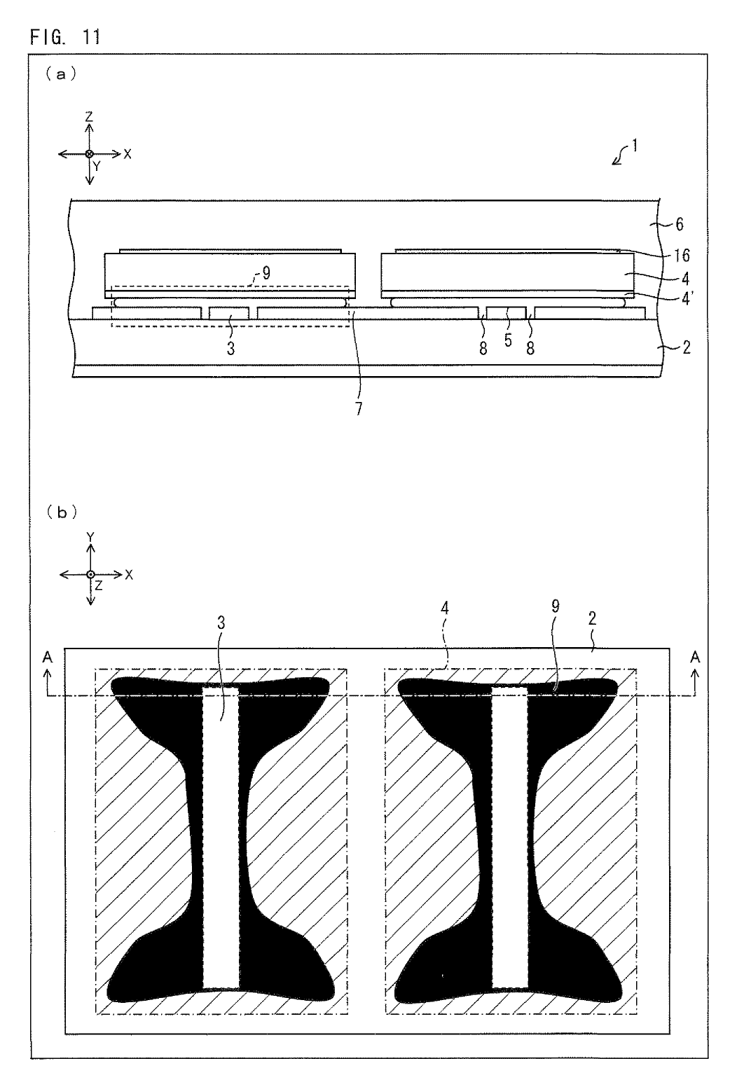

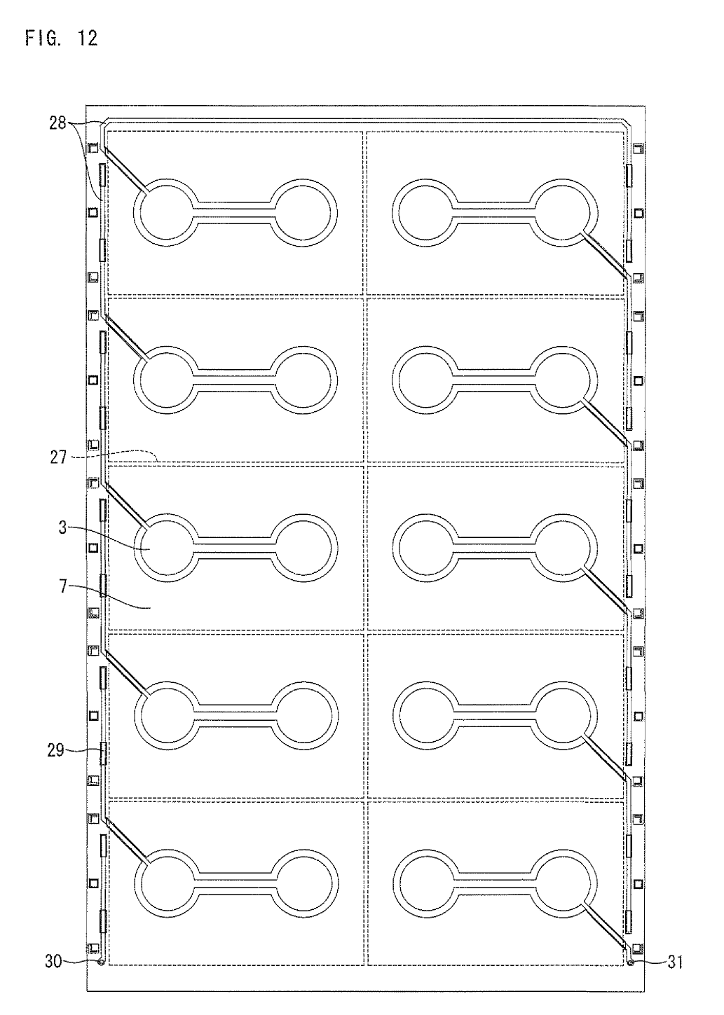

FIG. 12 is a plane view illustrating an interposer 2, interposer connecting terminals 3, and solder resists 7 before the semiconductor chip 4 is mounted. In FIG. 12, an I-shaped member shown in the central part of each chip mounting region 27 is the interposer connecting terminal 3. The solder resists 7 are formed in the outer side of the interposer connecting terminals 3.

In FIG. 12, the members denoted by the referential numeral 28 are leading lines formed, on the interposer 2 for serial connection. The members denoted by the referential numeral 29 are pads formed on the interposer 2 for wire bonding. The member denoted by the referential numeral 30 is a via hole for a negative electrode that leads to the mounting electrode 14 and a test pad on the backside of the interposer 2. The member denoted by the referential numeral 31 is a via hole for a positive electrode that leads to the mounting electrode 14 and a test pad on the backside of the interposer 2.

In the semiconductor package 1 and in the method of manufacturing the semiconductor package 1, the sealing resin 6 may be a light transmitting resin.

In the semiconductor package 1 and in the method of manufacturing the semiconductor package 1, the sealing resin 6 may be an epoxy resin or an acrylic resin.

In the semiconductor package 1 and in the method of manufacturing the semiconductor package 1, the semiconductor chip 4 may be a solar cell 12.

In the semiconductor package 1 and in the method of manufacturing the semiconductor package 1, the die bonding material may be an Ag paste 5.

In the semiconductor package 1 and in the method of manufacturing the semiconductor package 1, the solar cell 12 may have a thickness of 0.25 mm or less.

In the semiconductor package 1 and in the method of manufacturing the semiconductor package 1, a ratio T2/T1, which is obtained through dividing a thickness T2 of the sealing resin 6 on the solar cell by a thickness T1 of the solar cell 12, may be 1 or more and 2 or less.

In the semiconductor package 1 and in the method of manufacturing the semiconductor package 1, an area ratio obtained through dividing an area of the application region 9 by an area of the region 10 may be 1/4 or more and 3/2 or less.

The following describes an embodiment of the present invention with reference to FIGS. 14 to 25.

FIG. 14 is a cross-sectional view of a semiconductor package 32 according to an embodiment of the present invention. In the semiconductor package 32, a substrate wiring section 34 is formed on an interposer 33 on which a semiconductor chip 35 is to be mounted. A backside electrode 36 is formed on a backside of the semiconductor chip 35 (on a surface facing the interposer 33). The substrate wiring section 34 and the backside electrode 36 (electrode) are connected by conductive die bonding material (conductive adhesive) 37. In this manner, the semiconductor chip 35 and the interposer 33 are electrically connected with each other.

In FIG. 14, in a case where the semiconductor package 32 is a solar cell module, the semiconductor chip 35 is a solar cell. The substrate wiring section 34 is made of, e.g., copper, and the die bonding material 37 is, e.g., conductive silver paste. A backside electrode section 36a is made of, e.g., silver (the first metal), and a backside electrode section 36b is made of, e.g., aluminum (the second metal).

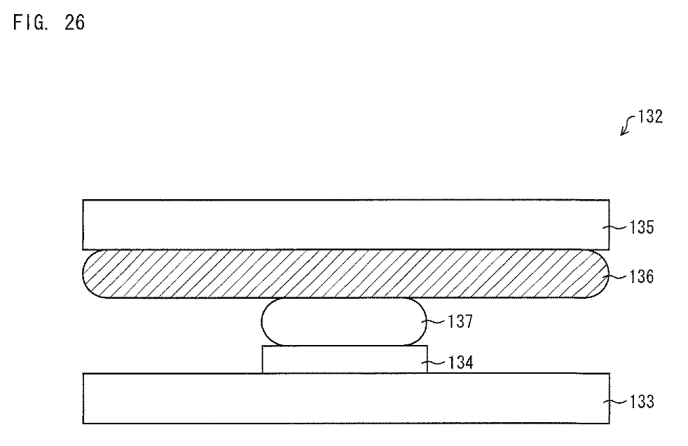

In a case where a conventional semiconductor package 132 illustrated in FIG. 26 is a solar cell, only burned aluminum, which is relatively porous, has been used for the backside electrode 136.

To the contrary, the semiconductor package 32 according to the embodiment of the present invention is provided with a backside electrode section 36a made of silver, with which a film having higher density can be formed than with burned aluminum, and a backside electrode section 36b made of burned aluminum. The adhesivity between silver and silver paste is higher than the adhesivity between aluminum and silver paste or the adhesivity between burned aluminum and silver paste. As such, it is possible to make the adhesivity at the interface between the backside electrode 36 made of burned aluminum and silver and the die bonding material 37 which is silver paste more intense than the adhesivity at the interface between the conventional backside electrode 136 made solely of burned aluminum and the die bonding material 137 which is silver paste. At the same time, this allows the contact resistance to be reduced. As a result, it becomes possible to provide a semiconductor package 32 with an improved long-term reliability as compared to the conventional semiconductor package 132.

In the semiconductor package 32 of FIG. 14, the sealing resin 39 is filled so as to surround the semiconductor chip 35. This makes it possible to further intensify the adhesivity at the interface between the backside electrode section 36a and the die bonding material 37. In the semiconductor package 32, the sealing resin 39 prevents the semiconductor chip 35 from warping and reduces the stress applied on the interface. In addition, the backside electrode section 36a made of silver allows the adhesivity at the interface adhered by the die bonding material 37 to be enhanced as compared to conventional semiconductor packages. As a result, it becomes possible to give a greater long-term reliability to a semiconductor package in comparison with conventional semiconductor packages.

Moreover, the backside electrode section 36b, which is made of, e.g., aluminum, is relatively porous. The conductive die bonding material 37 containing, e.g., silver contains an organic binder. Therefore, it is also expected that the stress applied on the semiconductor package 32 be reduced.

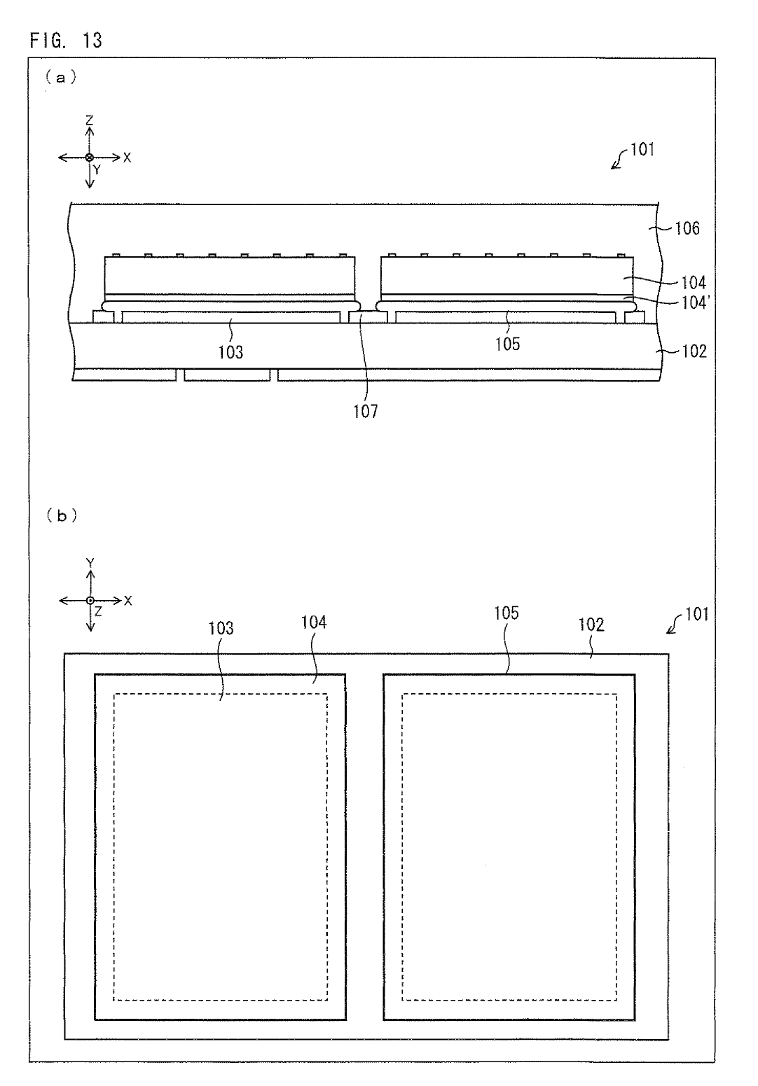

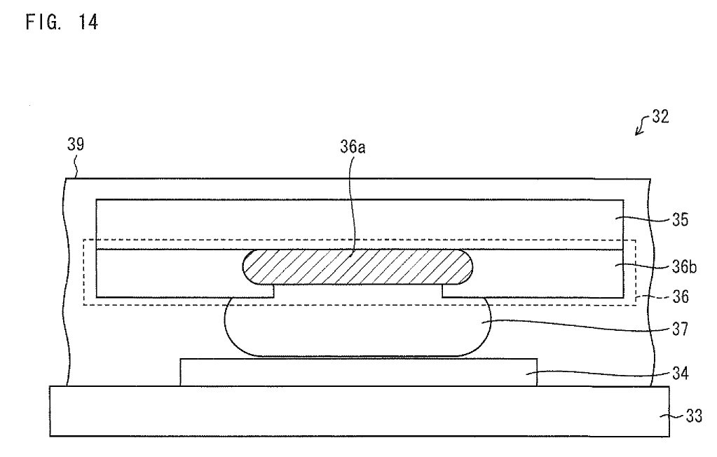

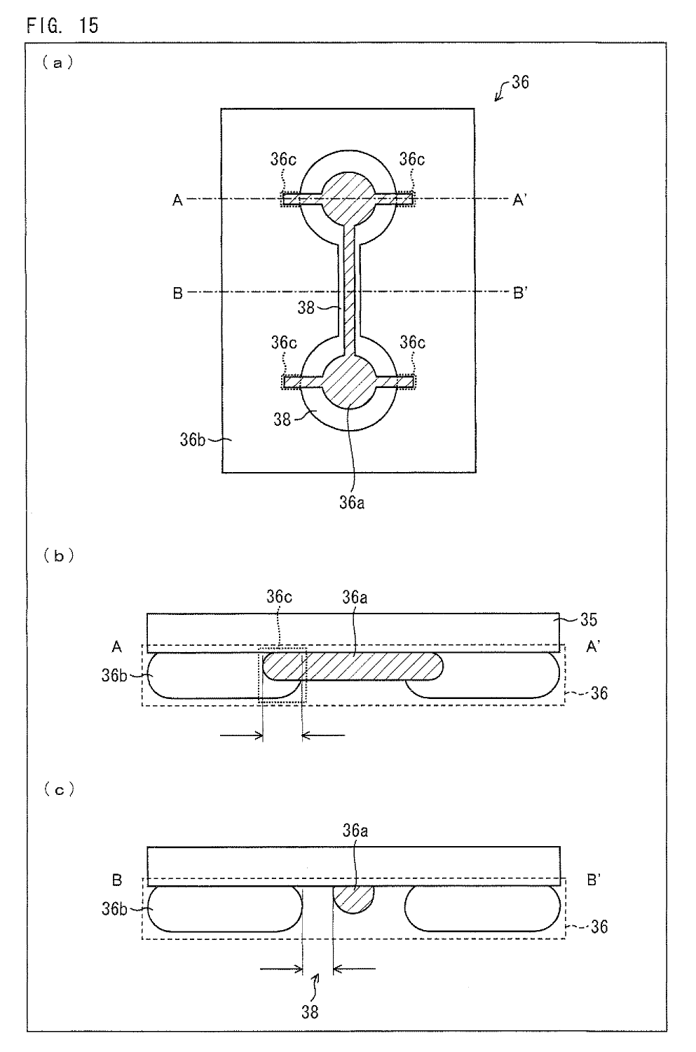

The following describes an example of the backside electrode 36 in the semiconductor chip 35 of the semiconductor package 32 with reference to FIGS. 15 to 25.

FIG. 15 is an illustrative drawing of a semiconductor chip 35 according to an embodiment of the present invention. (a) of FIG. 15 is a plane view of the semiconductor chip 35 according to the embodiment of the present invention seen below its backside. (b) of FIG. 15 is a cross-sectional view of the semiconductor chip 35 taken along the line A-A′ in (a) of FIG. 15. (c) of FIG. 15 is a cross-sectional view of the semiconductor chip 35 taken along the line B-B′ in (a) of FIG. 15.

As illustrated in (a) of FIG. 15, in the backside electrode 36, backside electrode sections 36a and after-mentioned overlapping sections 36c are formed to be substantially in the shape of an “I”. Around the backside electrode 36, a clearance 38 is formed. Furthermore, a backside electrode section 36b is formed so as to surround the clearance 38.

As illustrated in (a) and (b) of FIG. 15, the backside electrode 36 may include an overlapping section 36c where the backside electrode section 36a and the backside electrode section 36b overlap with each other. If the overlapping section 36c does not exist, photovoltaic is supplied from the backside electrode 36b via the conductive die bonding material 37 to the interposer 33. Even in such a case, the backside electrode 36a helps to improve the adhesivity to the conductive die bonding material 37. On the other hand, when the overlapping section 36c does exist, an additional path is provided for supplying photovoltaic from the backside electrode section 36b via the backside electrode section 36a and the conductive die bonding material 37 to the interposer 33.

Moreover, as illustrated in (a) and (c) of FIG. 15, the backside electrode 36 may be provided with a clearance 38 between the backside electrode section 36a and the backside electrode section 36b. The clearance 38 may be filled with a conductive silver paste that serves as a die bonding material 37, or a part of the clearance 38 may be a gap.

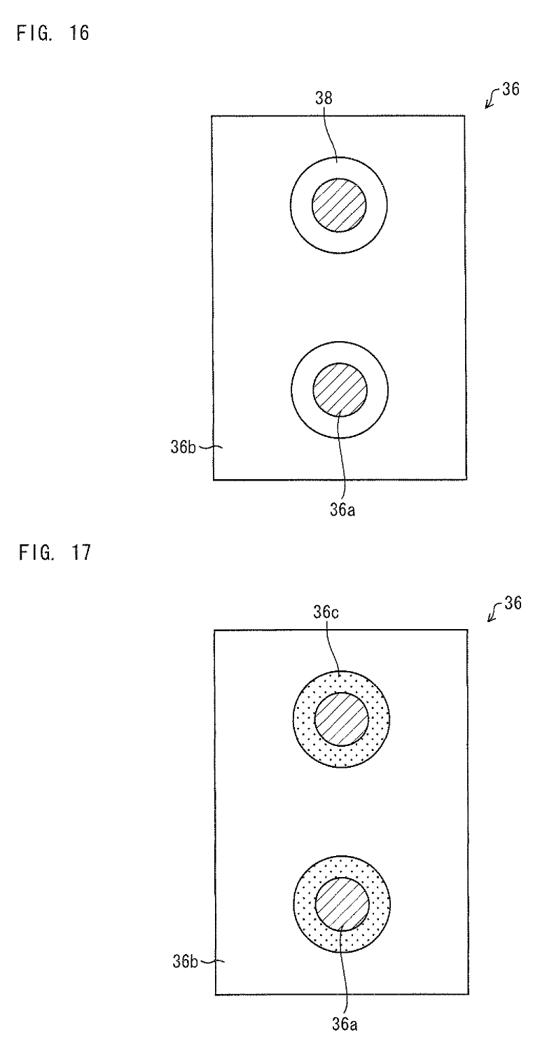

FIG. 16 is a plane view of another semiconductor chip 35 according to the embodiment of the present invention seen below its backside. The semiconductor chip 35 of FIG. 16 includes two circular backside electrode sections 36a. Around the circular electrode sections 36a are formed ring-shaped clearances 38. A backside electrode section 36b is formed in the outer side of the ring-shaped clearances 38.

FIG. 17 is a plane view of still another semiconductor chip 35 according to the embodiment of the present invention seen below its backside. The semiconductor chip 35 of FIG. 17 includes two circular backside electrode sections 36a. Around the circular backside electrode sections 36a are formed ring-shaped overlapping sections 36c. A backside electrode section 36b is provided in the outer side of the ring-shaped overlapping sections 36c.

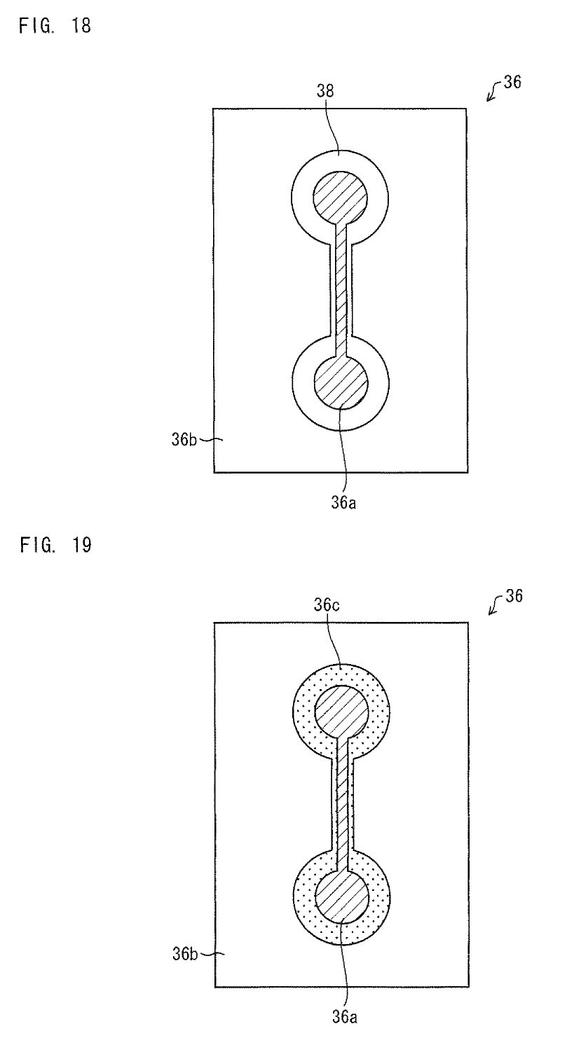

FIG. 18 is a plane view of still another semiconductor chip 35 according to the embodiment of the present invention seen below its backside. In the semiconductor chip 35 of FIG. 18, a backside electrode section 36a has such a shape that a circular electrode section is connected to each shorter sides of a rectangular electrode section. Around the backside electrode section 36a having such a shape, a clearance 38 is provided. A backside electrode section 36b is formed in the outer side of the clearance 38.

FIG. 19 is a plane view of still another semiconductor chip 35 according to the embodiment of the present invention seen below its backside. In the semiconductor chip 35 of FIG. 19, a backside electrode sections 36a have such a shape that a circular backside electrode section is connected to each shorter sides of a rectangular backside electrode section. Around the backside electrode section 36a having such a shape, an overlapping section 36c is provided. A backside electrode section 36b is formed in the outer side of the overlapping section 36c.

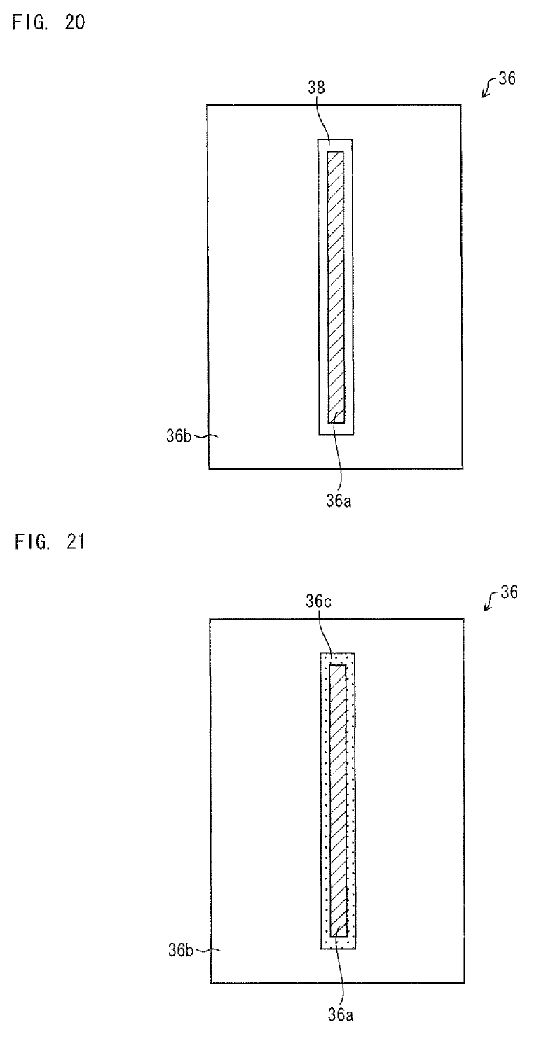

FIG. 20 is a plane view of still another semiconductor chip 35 according to the embodiment of the present invention seen below its backside. In the semiconductor chip 35 of FIG. 20, a backside electrode section 36a is rectangular. The backside electrode section 36a has, for example, shorter sides that are parallel to the shorter sides of the backside electrode 36 and longer sides that are parallel to the longer sides of the backside electrode 36. Around the backside electrode section 36a having such a shape, a clearance 38 is provided. A backside electrode section 36b is formed in the outer side of the clearance 38.

The backside electrode section 36a may rotate 90 degrees from the state illustrated in FIG. 20. That is, the backside electrode section 36a may be a rectangle whose shorter sides are parallel to the longer sides of the backside electrode 36 and whose longer sides are parallel to the shorter sides of the backside electrode 36.

FIG. 21 is a plane view of still another semiconductor chip 35 according to the embodiment of the present invention seen below its backside. In the semiconductor chip 35 of FIG. 21, a backside electrode section 36a is rectangular. The backside electrode section 36a is, for example, a rectangle whose shorter sides are parallel to the shorter sides of the backside electrode 36 and whose longer sides are parallel to the longer sides of the backside electrode 36. Around the backside electrode section 36a having such a shape, an overlapping section 36c is formed. A backside electrode section 36b is formed in the outer side of the overlapping section 36c.

The backside electrode section 36a may rotate 90 degrees from the state shown in FIG. 21. That is, the backside electrode section 36a may be a rectangle whose shorter sides are parallel to the longer sides of the backside electrode 36 and whose longer sides are parallel to the shorter sides of the backside electrode 36.

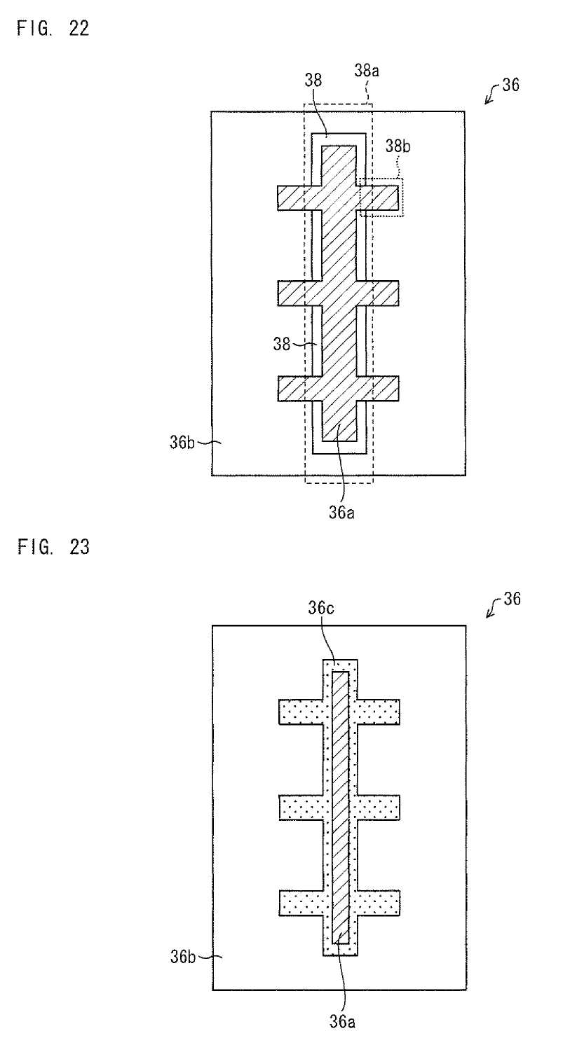

FIG. 22 is a plane view of still another semiconductor chip 35 according to the embodiment of the present invention seen below its backside. In the semiconductor chip 35 of FIG. 22, the backside electrode section 36a has such a shape that three cross-shapes (+) are connected in a lateral direction. In FIG. 22, the lateral direction is a direction along which the longer sides of the backside electrode 36 extend. Around the backside electrode section 36a are provided a region 38a where the clearance 38 is provided and a region 38b where the backside electrode section 36b is provided. However, it is also possible to form only the region 38a around the backside electrode section 36a, or to form only the region 38b around the backside electrode section 36a. That is, it is also possible to form only the clearance 38 around the backside electrode section 36a, or to form only the backside electrode section 36b around the backside electrode section 36a.

FIG. 23 is a plane view of still another semiconductor chip 35 according to the embodiment of the present invention seen below its backside. In the semiconductor chip 35 of FIG. 23, an overlapping section 36c has such a shape that three cross-shapes (+) are connected in a lateral direction. The lateral direction in FIG. 23 means a direction along which the longer sides of the backside electrode 36 extend. The semiconductor chip 35 of FIG. 23 includes a backside electrode section 36a in the overlapping section 36c. In the semiconductor chip 35 of FIG. 23, the backside electrode section 36a is a rectangle whose shorter sides are parallel to the shorter sides of the backside electrode 36 and whose longer sides are parallel to the longer sides of the backside electrode 36.

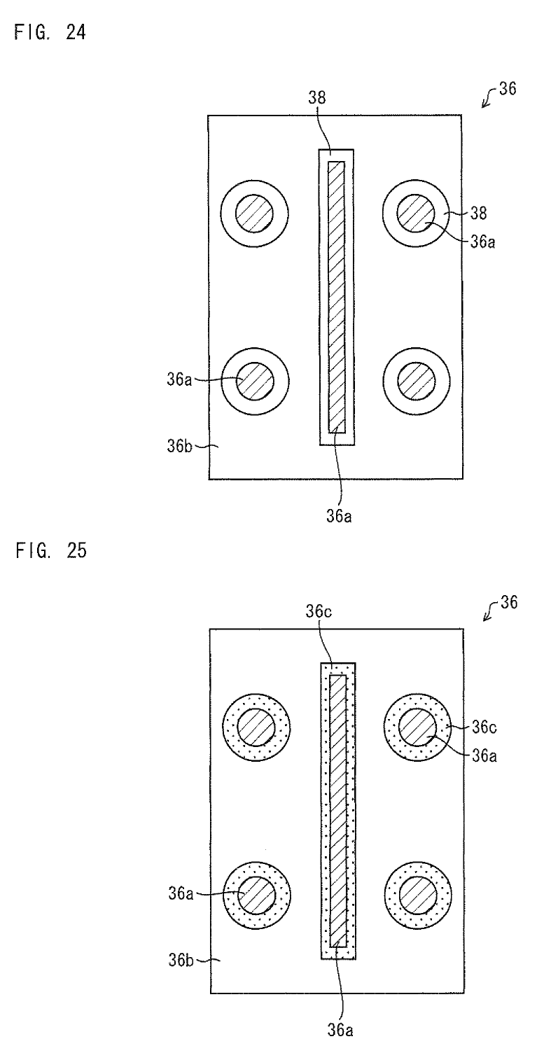

FIG. 24 is a plane view of still another semiconductor chip 35 according to the embodiment of the present invention seen below its backside. In the semiconductor chip 35 of FIG. 24, a backside electrode 36 has a rectangular backside electrode section 36a which longer sides are parallel to the longer sides of the backside electrode 36, and four circular backside electrode sections 36a. The rectangular backside electrode section 36a is disposed in the central part of the backside electrode 36, and the four circular backside electrode sections 36a are respectively disposed on the four corners of the semiconductor chip 35. Consequently, the backside electrode sections 36a are disposed so as to form substantially a shape of an “I”. Around each backside electrode section 36a, a clearance 38 is formed. A backside electrode section 36b is formed in the outer side of each clearance 38.

FIG. 25 is a plane view of still another semiconductor chip 35 according to the embodiment of the present invention seen below its backside. A backside electrode 36 has a rectangular backside electrode section 36a whose longer sides are parallel to the longer sides of the backside electrode 36 and four circular backside electrode sections 36a. The rectangular backside electrode 36 is disposed in the central part of the backside electrode 36, and the four circular backside electrode sections 36a are respectively disposed on the four corners of the semiconductor chip 35. Consequently, the backside electrode sections 36a are disposed so as to form substantially a shape of an “I”. Around each backside electrode section 36a, an overlapping section 36c is formed. A backside electrode section 36b is formed in the outer side of each overlapping section 36c.

In the semiconductor package 32, the backside electrode section 36a may be smaller than the backside electrode section 36b.

In the semiconductor package 32, a part of the backside electrode section 36a and a part of the backside electrode section 36b may overlap with each other.

Moreover, in the semiconductor package 32, the backside electrode section 36a may be ranged in the central part of the semiconductor chip 35, and the backside electrode section 36b may be ranged at the periphery of the semiconductor chip 35.

Furthermore, in the semiconductor package 32, the backside electrode section 36a may be present as portions scattered about on the semiconductor chip 35, and the backside electrode section 36b may be ranged at the periphery of the semiconductor chip 35.

In the semiconductor package 32, 80% or more of the die bonding material 37 may reside in the backside electrode section 36a.

In the semiconductor package 32, a region in which the die bonding material 37 resides and a region in which a sealing resin 39 resides may be formed between the semiconductor chip 35 and the interposer 33.

In the semiconductor package 32, the semiconductor chip 35 may be a solar cell.

Similarly to (a) and (b) of FIG. 15, the backside electrode 36 of the semiconductor chip 35 of FIGS. 17, 19, 21, 23, and 25 may include the overlapping section 36c.

### INDUSTRIAL APPLICABILITY

With the semiconductor package and the method of manufacturing a semiconductor package according to the present invention, it is possible to improve electrical property and long-term reliability in comparison with conventional semiconductor packages and to prevent a semiconductor chip from warping. Therefore, the present invention can be adopted to semiconductor packages in which a detachment at the adhesive interface or a warp of the semiconductor chip would occur.

Because the semiconductor package of the present invention has an improved long-term reliability in comparison with conventional semiconductor packages, it can be preferably adopted for small-sized portable equipments.

### REFERENCE SIGNS LIST

1 Semiconductor Package
2 Interposer
3 Interposer Connecting Terminal
4 Semiconductor Chip
4′ Backside
5 Ag Paste (Silver Paste, Conductive Die-Bonding Material)
6 Sealing Resin
7 Solder Resist
9 Application Region (First Region)
10 Region (Second Region)
11 Solar Cell Module
12 Solar Cell
13 Module Substrate
14 Mounting Electrode
15 Sintered Material
16 Connecting Section
17 p-Layer
18 Aluminum
n+ Layer
p+ Layer
21 Cellular Phone
22 Operation Surface
23 Screen
24 Fulcrum
25 Camera
26 Battery Cover
27 Chip Mounting Region
28 Leading Line for Serial Connection
29 Pad for Wire Bonding
30 Via Hole for Negative Electrode
31 Via Hole for Positive Electrode
I Current Source
L Load
R1 Current Equivalent Resistance
R2 Series Resistance
32 Semiconductor Package
33 Interposer
34 Substrate Wiring Section
35 Semiconductor Chip
36 Backside Electrode (Electrode)
36a Backside Electrode Section (First Region)
36b Backside Electrode Section (Second Region)
36c Overlapping Section
37 Die-Bonding Material
38 Clearance
38a, 38b Regions
39 Sealing Resin

1. A semiconductor package including: a semiconductor chip; an interposer on which the semiconductor chip is mounted; and a sealing resin covering the semiconductor chip on the interposer,
the semiconductor chip and the interposer being bonded by a conductive die bonding material,
the semiconductor package having, between the semiconductor chip and the interposer, a first region in which the die bonding material resides, and a second region in which the sealing resin resides.

2. The semiconductor package according to claim comprising a connecting section on a surface of the semiconductor chip, which surface is opposite to a surface thereof facing the interposer, the connecting section electrically connecting the semiconductor chip with the interposer,
the interposer and the connecting section being bonded by wire bonding, wherein:
the die bonding material is provided on the surface of the semiconductor chip facing the interposer correspondingly to the connecting section formed on the opposite surface of the semiconductor chip.

3. The semiconductor package according to claim 1, wherein:
the sealing resin is a light transmitting resin.

4. The semiconductor package according to claim 3, wherein:
the sealing resin is an epoxy resin or an acrylic resin.

5. The semiconductor package according to claim 1, wherein:
the semiconductor chip is a solar cell.

6. The semiconductor package according to claim 1, wherein:
the die bonding material is a silver paste.

7. The semiconductor package according to claim 5, wherein:
the solar cell has a thickness of 0.25 mm or less.

8. The semiconductor package according to claim 7, wherein:
a ratio obtained through dividing a thickness of the sealing resin on the solar cell by the thickness of the solar cell is 1 or more and 2 or less.

9. The semiconductor package according to claim 1, wherein:
an area ratio obtained through dividing an area of the first region by an area of the second region is 1/4 or more and 3/2 or less.

10. A semiconductor package including: a semiconductor chip; an interposer on which the semiconductor chip is mounted; and a sealing resin covering the semiconductor chip on the interposer, wherein:
an electrode formed on a surface of the semiconductor chip, which surface faces the interposer, has a first region containing a first metal and a second region containing a second metal,
the interposer and the electrode being electrically connected with each other by a conductive die bonding material containing the first metal.

11. The semiconductor package according to claim 10, wherein:
the first metal is silver and the second metal is aluminum.

12. The semiconductor package according to claim 10, wherein:
the first metal is silver, and the second metal is burned aluminum.

13. The semiconductor package according to claim 11, wherein:
the die bonding material containing the first metal is a silver paste.

14. The semiconductor package according to claim 10, wherein:
the first region is smaller than the second region.

15. The semiconductor package according to claim 10, wherein:
a part of the first region and a part of the second region overlap with each other.

16. The semiconductor package according to claim 10, wherein:
the first region is ranged in a central part of the semiconductor chip, and the second region is ranged at a periphery of the semiconductor chip.

17. The semiconductor package according to claim 10, wherein:
the first region is present as portions scattered about on the semiconductor chip, and the second region is ranged at a periphery of the semiconductor chip.

18. The semiconductor package according to claim 10, wherein:
80% or more of the die bonding material resides in the first region.

19. The semiconductor package according to claim 10, wherein:
a region in which the die bonding material resides and a region in which the sealing resin resides are formed between the semiconductor chip and the interposer.

20. The semiconductor package according to claim 10, wherein:
the semiconductor chip is a solar cell.
